(19) United States
(12) Patent Application Publication
(10) Pub. No.: US 2013/0276873 A1
(43) Pub. Date: Oct. 24, 2013

(54) HIGH LEVEL INJECTION SYSTEMS

(71) Applicant: CALIFORNIA INSTITUTE OF TECHNOLOGY, Pasadena, CA (US)

(72) Inventors: Elizabeth Santori, Bethesda, MD (US); Nathan S. Lewis, La Canada Flintridge, CA (US); Harry A. Atwater, South Pasadena, CA (US)

(21) Appl. No.: 13/867,066

(22) Filed: Apr. 20, 2013

Related U.S. Application Data
(60) Provisional application No. 61/636,323, filed on Apr. 20, 2012.

(51) Int. Cl. H01L 31/0352

(52) U.S. Cl. CPC H01L 31/03529
USPC 136/255

(57) ABSTRACT

A semiconductor device having elongated structure having high-level injection are provided, as well as making and using such devices.

### CROSS REFERENCE TO RELATED APPLICATIONS

This application claims priority to U.S. Provisional Application Ser. No. 61/636,323, filed Apr. 20, 2012, the disclosure of which is incorporated herein by reference.

### STATEMENT REGARDING FEDERALLY SPONSORED RESEARCH

This invention was made with government support under grant numbers DE-FG02-05ER15754 (T-105327) awarded by the U.S. Department of Energy. The government has certain rights in the invention.

### TECHNICAL FIELD

This invention relates to photovoltaic cells, devices, methods of making and uses thereof.

### BACKGROUND

Ordered arrays of crystalline-Si (c-Si) microwires, fabricated by the chemical-vapor-deposition, vapor-liquid-solid (CVD-VLS) growth mechanism, were pioneered nearly five years ago for sunlight-to-electrical power conversion. P-type Si microwire arrays, employing a thin n⁺-doped emitter layer to form a buried junction (n⁺p-Si), have since realized sunlight-to-electrical power-conversion efficiencies >7% from solid-state photovoltaic (PV) devices, and >5% power-conversion efficiency toward H₂ evolution from acidic aqueous electrolytes when functionalized with Pt electrocatalysts.

### SUMMARY

The disclosure provides a device comprising a back contact layer; an ordered array of elongated intrinsic or lightly doped semiconductor structures, wherein the elongate structures have length dimensions defined by adjacent ends in electrical contact with at least portions of the back contact layer and distal ends not in contact with the back contact layer and have radial dimensions generally normal to the length dimensions and the radial dimensions are less than the length dimensions and wherein the diameters of the elongated structures are greater than 500 nm; and an axial or radial contact layer or medium, wherein at least some portions of the axial or radial contact layer or medium are in electrical contact with one or more elongate structures of the plurality of the elongate structures along at least portions of the length dimensions of the one or more elongate semiconductor structures, wherein the elongate structures absorb received light. In one embodiment, the radial dimensions are less than or equal to minority carrier diffusion lengths for material comprising the elongate semiconductor structures. In another embodiment, the elongated structures comprise minority carrier lifetimes of greater than 1 μs. In yet another embodiment, the elongated structures comprise diameters greater than 500 nm. In yet another embodiment, the elongated structures comprise diameters of about 1.75 μm to 3 μm. In yet another embodiment of any of the foregoing, the elongated structures' acceptor concentrations (Na) are ˜1×10¹³ to 10¹⁴ cm⁻³. In yet another embodiment, the elongated structures' donor acceptor concentrations (Nd) are ˜1×10¹³ to 10¹⁴ cm⁻³. In another embodiment, the back contact is an n⁺-type contact when the radial or axial contact is p⁺-type. In yet another embodiment, the back contact is a p⁺-type contact when the radial or axial contact is n⁺-type. In yet a another embodiment, the elongated structure produces 450 or greater mV. In another embodiment of any of the foregoing, the device displays high level injection characteristics. In another embodiment of the foregoing, the base contact layer comprises a substrate and the elongate semiconductor structures comprise structures grown from the substrate. In yet another embodiment of any of the foregoing, the base contact layer comprises a substrate and the elongate semiconductor structures comprise structures deposited on the substrate. In another embodiment of any of the foregoing the axial or radial contact layer comprises a liquid electrolyte. In yet another embodiment, the device further comprises a catalyst in contact with the back contact layer. In yet another embodiment, the device further comprises a catalyst in contact with the elongated structures. The catalyst can be a hydrogen evolution catalyst selected from the group consisting of Pt, Co, Cu, Fe, MoSₓ where x is nominally 2, but may be sub or super-stoichiometric, Ni, CoMo, CoW, FeMo, NiCo, NiFe, NiFeC, NiFeS, NiMnS, NiMo, NiMoP, NiSn, NiW, NiZn, NiZnP, CoNiFe, NiCoPMo, NiMoCo, NiMoCu, NiMoFe, NiMoW, NiSiMo, NiSiW and NiWPCu. The catalyst can be an oxygen evolution catalyst selected from the group consisting of IrOₓ where x is nominally 2, but may be sub or super-stoichiometric, Pt, Co, Co/(PO₄)³⁻, Co/(BO₃)³⁻, CoP, Cu, Fe, Mn, Ni, Ni/(B₃)³⁻,NiP, Pb, CoFe, CoPSc₂O, FeMn, NiCo, NiCr, NiCu, NiFe, NiLa, NiPSc₂O₃, NiSn, NiZn and NiMoFe. In another embodiment of any of the foregoing, the elongated structure comprise a material selected from the group consisting of elements from Group IV of the periodic table; elements from Group III and Group V of the periodic table; elements from Group II and Group VI of the periodic table; elements from Group I and Group VII of the periodic table; elements from Group IV and Group VI of the periodic table; elements from Group V and Group VI of the periodic table; and elements from Group II and Group V of the periodic table. In yet another embodiment, the elongated structure comprises a material selected form the group consisting GaAs, GaP, GaAsₓP₁₋ₓ, AlₓGa₁₋ₓ, As, AlₓGa₁₋ₓAs_{y}P_{1-y}, InₓGa₁₋ₓAs, InₓGa₁₋ₓP, InₓGa₁₋ₓAs_{y}P_{1-y}, AlₓIn₁₋ₓAs_{y}P_{1-y}, AlₓGa₁₋ₓAs_{y}N_{z}P_{1-y-z}, InₓGa₁₋ₓAs_{y}N_{z}P_{1-y-z}, Zn₃P₂, Zn₃S₂, and ZnPₓS₁₋ₓ(0≦x≦1, 0≦y≦1, 0≦z≦1, 0≦y+z≦1). In yet another embodiment, the elongated structure comprises a material selected from the group consisting of TiO₂, CaTiO₃, SrTiO₃, Sr₃Ti₂O₇, Sr₄Ti₃O₁₀, Rb₂La₂Ti₃O₁₀, Cs₂La₂Ti₃O₁₀, CsLa₂Ti₂NbO₁₀, La₂TiO₅, La₂Ti₃O₉, La₂Ti₂O₇, La₂Ti₂O₇:Ba, KaLaZr_{0.3}Ti_{0.7}O₄, La₄CaTi₅O₁₇, KTiNbO₅, Na₂Ti₆O₁₃, BaTi₄O₉, Gd₂Ti₂O₇, Y₂Ti₂O₇, ZrO₂, K₄N₆O₁₇, Rb₄Nb₆O₁₇, Ca₂Nb₂O₇, Sr₂Nb₂O₇, Ba₅Nb₄O₁₅, NaCa₂Nb₃O₁₀, ZnNb₂O₆, Cs₂Nb₄₀n, La₃NbO₇, Ta₂O₅, KsPrTa₅O₁₅, K₃Ta₃Si₂O₁₃, K₃Ta₃B₂O₁₂, LiTaO₃, KTaO₃, AgTaO₃, KTaO₃:Zr, NaTaO₃:La, NaTaO₃:Sr, Na₂Ta₂O₆, CaTa₂O₆, SrTa₂O₆, NiTa₂O₆, Rb₄Ta₆O₁₇, Ca₂Ta₂O₇, Sr₂Ta₂O₇, K₂SrTa₂O₇, RbNdTa₂O₇, H₂La_{2/3}Ta₂O₇, K₂Sr_{1.5}Ta₃O₁₀, LiCa₂Ta₃O₁₀, KBa₂Ta₃O₁₀, Sr₅Ta₄O₁₅, Ba₂Ta₄O₁₅, H_{1.8}Sr_{0.81}Bi_{0.19}Ta₂C₇, Mg—Ta Oxide, LaTaO₄, LaTaO₇, PbWO₄, RbWNbO₆, RbWTaO₆, CeO₂:Sr, BaCeO₃, NaInO₂, CaIn₂O₄, SrIn₂O₄, LaInO₃, YxIn₂₋ₓO₃, NaSbO₃, CaSb₂O₆, Ca₂Sb₂O₇, Sr₂Sb₂O₇, Sr₂SnO₄, ZnGa₂O₄, Zn₂GeO₄, LiInGeO₄, Ga₂O₃^{b}, Ga₂O₃:Zn^{c}, Na₂Ti₃O₇, K₂Ti₂O₅, K₂Ti₄O₉, Cs₂Ti₂O₅, H⁺—Cs₂Ti₂O₅, Cs₂Ti₅O₁₁, Cs₂Ti₆O₁₃, H⁺—CsTiNbO₅, H⁺—CsTi₂NbO₇, SiO₂-pillared K₂Ti₄O₉, SiO₂-pillared K₂Ti_{2.7}Mn_{0.3}O₇, Na₂W₄O₁₃, H⁺—KLaNb₂O₇, H⁺—RbLaNb₂O₇, H⁺—CsLaNb₂O₇, H⁺—KCa₂Nb₃O₁₀, SiO₂-pillared KCa₂Nb₃O₁₀, ex-Ca₂Nb₃O₁₀/K⁺ nanosheet⁴⁾, Restacked ex-Ca₂Nb₃O₁₀/Na⁺, H⁺—RbCa₂Nb₃O₁₀, H⁺—CsCa₂Nb₃O₁₀, H⁺—KSr₂Nb₃O₁₀, H⁺—KCa₂NaNb₄O₁₃, Bi₂W₂O₉, Bi₂Mo₂O₉, Bi₄Ti₃O₁₂, BaBi₄Ti₄O₁₅, Bi₃TiNbO₉, PbMoO₄, (NaBi)_{0.5}MoO₄, (AgBi)_{0.5}MoO₄, (NaBi)_{0.5}WO₄, (AgBi)_{0.5}WO₄, Ga_{1.14}In_{0.86}O₃, β-Ga₂O₃, Ti_{1.5}Zr_{1.5}(PO₄)₄, WO₃, Bi₂WO₆, Bi₂MoO₆, Bi₂Mo₃O₁₂, Zn₃V₂O₈, Na_{0.5}Bi_{1.5}VMoO₈, In₂O₃ (ZnO)₃, SrTiO₃:Cr/Sb, SrTiO₃:Ni/Ta, SrTiO:Cr/Ta, SrTiO:Rh, CaTiO:Rh, La₂Ti₂O₇:Cr, La₂Ti₂O₇:Fe, TiO₂: Cr/Sb, TiO₂:Ni/Nb, TiO₂:Rh/Sb, PbMoO₄:Cr, RbPb₂Nb₃O₁₀, PbBi₂Nb₂O₉, BiVO₄, BiCu₂VO₆, BiZn₂VO₆, SnNb₂O₆, AgNbO₃, Ag₃VO₄, AgLi_{1/3}Ti_{2/3}O₂, AgLi_{1/3}Sn_{2/3}O₂, LaTiO₂N, Ca_{0.25}La_{0.75}TiO_{2.25}N_{0.75}, TaON, Ta₃N₅, CaNbO₂N, CaTaO₂N, SrTaO₂N, BaTaO₂N, LaTaO₂N, Y₂Ta₂O₅N₂, TiNₓO_{y}F_{z}, Sm₂Ti₂O₅S₂ and La—In oxysulfide. In a specific embodiment, the elongated structure comprise Si. In yet another embodiment, the elongated structure comprise at least one of the following materials: crystalline silicon; amorphous silicon; micromorphous silicon; protocrystalline silicon; nanocrystalline silicon; cadmium telluride; copper-indium selenide; copper indium gallium selenide gallium arsenide; gallium arsenide phosphide; cadmium selenide; indium phosphide; a-Si:H alloy, and combinations thereof. In another embodiment, the disclosure provides a photocell comprising a device described herein or a photocell for conversion of water to hydrogen comprising a device of the disclosure.

### BRIEF DESCRIPTION OF THE DRAWINGS

FIG. 1A-B shows scanning electron microscopy images. (A) Side view scanning electron microscopy image of a cleaved array of square-packed Si microwires. Scale bar=30 μm. B) Top view of the same Si microwire array. Scale bar=20 μm.

FIG. 2A-B show plots of current density vs. potential (J-E) behavior of (A) n⁺i-Si and (B) p⁺i-Si microwire arrays in contact with Me₂Fc^{+/0}-CH₃OH under 100 mW cm⁻² of ELH-type W halogen illumination, and in the dark.

FIG. 3A-B show J-E behavior of (A) n⁺i-Si and (B) p⁺i-Si microwire arrays in contact with CoCp₂^{+/0}-CH₃CN under 100 mW cm⁻² of ELH-type W halogen illumination, and in the dark.

FIG. 4 shows J-E data as a function of illumination intensity at 808 nm for a representative n⁺i-Si microwire array photoelectrode in contact with 200 mM Me₂Fc/40 mM Me₂FcBF₄ in methanol.

FIG. 5 is a plot of the external quantum yield and internal quantum yields of as-grown and polished n⁺i-Si microwire array photoelectrodes measured in contact with 200 mM Me₂Fc/40 mM Me₂FcBF4 in methanol.

FIG. 6 shows a diagram of the concentration of holes within a single undoped wire in contact with Me₂Fc^{+/0}-CH₃OH in the dark, as a function of the distance radially within the wire, for two different wire diameters, D=0.2 and 2.4 μm, as calculated from device physics simulations.

FIG. 7 is a schematic of the scanning internal quantum yield simulation for a single wire, where the internal quantum yield is calculated as a function of the distance of the excitation from the top of the wire.

FIG. 8 graphs the variation of the carrier-collection efficiency along the axial direction of a single wire with the dopant density Nd, for a wire with a typical diameter D=2.4 μm and a fixed lifetime of 1 μs, as calculated from device physics simulations.

FIG. 9A-C are graphs of the variation of the carrier-collection efficiency along the axial direction of a single wire with the change in the radius of the wire, as calculated from device physics simulations, for a fixed dopant density N_{d}=6.3×10¹³ cm⁻³and for lifetimes of A) 1 μs, B) 5 μs, and C) 10 μs.

### DETAILED DESCRIPTION

As used herein and in the appended claims, the singular forms “a,” “and,” and “the” include plural referents unless the context clearly dictates otherwise. Thus, for example, reference to “a pillar” includes a plurality of such pillars and reference to “the catalyst” includes reference to one or more catalysts known to those skilled in the art, and so forth.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of.”

Unless defined otherwise, all technical and scientific terms used herein have the same meaning as commonly understood to one of ordinary skill in the art to which this disclosure belongs. Although methods and materials similar or equivalent to those described herein can be used in the practice of the disclosed methods and compositions, the exemplary methods, devices and materials are described herein.

The publications discussed above and throughout the text are provided solely for their disclosure prior to the filing date of the present application. Nothing herein is to be construed as an admission that the inventors are not entitled to antedate such disclosure by virtue of prior disclosure.

By “about” is meant a quantity, level, value, number, frequency, percentage, dimension, size, amount, weight or length that varies by as much as 30, 25, 20, 25, 10, 9, 8, 7, 6, 5, 4, 3, 2 or 1% to a reference quantity, level, value, number, frequency, percentage, dimension, size, amount, weight or length. With respect to ranges of values, the invention encompasses each intervening value between the upper and lower limits of the range to at least a tenth of the lower limit's unit, unless the context clearly indicates otherwise. Further, the invention encompasses any other stated intervening values. Moreover, the invention also encompasses ranges excluding either or both of the upper and lower limits of the range, unless specifically excluded from the stated range.

The term “array” generally refers to multiple numbers of structures distributed within an area and spaced apart, unless otherwise indicated. Structures within an array all do not have to have the same orientation.

The term “aspect ratio” refers to the ratio of a structure's length to its width. Hence, the aspect ratios of the elongate structures will be greater than one. In various embodiments, the diameter of, for example, a “rod” or “wire” is about 10 nm-50 nm, about 50 nm-100 nm, about 100 nm-500 nm, about 500 nm-1 μm, about 1 μm-10 μm or about 10 μm-100 μm. Typically the diameter will be about 1 μm-10 μm. The length of the “rod” or “wire” is about 1 μm-10 μm, about 10 μm-100 μm, or about 100 μm-several millimetres.

The terms “ball,” “spheroid,” “blob” and other similar terms may also be used synonymously, except as otherwise indicated. Generally, these terms refer to structures with the width defined by the longest axis of the structure and the length defined by the axis generally normal to the width. Hence, the aspect ratio of such structures will generally be unity or less than unity.

The terms “ordered” or “well-defined” generally refer to the placement of elements in a specified or predetermined pattern where the elements have distinct spatial relationships to one another. Hence, the terms “ordered array” or “well-defined” generally refer to structures distributed within an area with distinct, specified or predetermined spatial relationships to one another. For example, the spatial relationships within an ordered array may be such that the structures are spaced apart from one another by generally equal distances. Other ordered arrays may use varying, but specified or predetermined, spacings. The structures within “ordered” or “well-defined” arrays may also have similar orientations with respect to each other.

A “photovoltaic cell” is an electrical device comprising a semiconductor that converts light or other radiant energy, in the range from ultraviolet to infrared radiation, incident on its surface into electrical energy in the form of power/voltage/current and which has two electrodes, usually a diode with a top electrode and a bottom electrode with opposite electrical polarities. The photovoltaic cell produces direct current which flows through the electrodes. As employed herein, the term photovoltaic cell is generic to cells which convert radiant energy into electrical energy. A solar cell is a photocell that converts light, including solar radiation, incident on its surface into electrical energy. Electromagnetic Radiation to Electric Energy Conversion Device (EREECD) is a device that reacts with electromagnetic (optical) radiation to produce electrical energy. Optoelectronic Energy Device (OED) refers to a device that reacts with optical radiation to produce electrical energy with an electronic device.

A photovoltaic (“PV”) cell may be connected in parallel, in series, or a combination thereof with other such cells. A common PV cell is a p-n junction device based on crystalline silicon. In various embodiments of the disclosure a PV cell comprises p-n junction devices of silicon microwires. Other types of PV cells can be based on a p-n junction cell of silicon and other semiconductive materials, such as, but not limited to, amorphous silicon, polycrystalline silicon, germanium, organic materials, and Group III-V semiconductor materials, such as gallium arsenide (GaAs).

During operation of a photovoltaic cell, incident solar or light radiation penetrates below a surface of the PV cell and is absorbed. The depth at which the solar radiation penetrates depends upon an absorption coefficient of the cell. In the case of a PV cell based on silicon, an absorption coefficient of silicon varies with wavelength of solar radiation. At a particular depth within the PV cell, absorption of solar radiation produces charge carriers in the form of electron-hole pairs. Electrons flow through one electrode connected to the cell, while holes exit through another electrode connected to the cell. The effect is a flow of an electric current through the cell driven by incident solar radiation. Inefficiencies exist in current solar cells due to the inability to collect/use and convert the entire incident light.

As used herein, the term “n-type” refers to a semiconductor that is doped to possess an excess of negative charge carriers, i.e. electrons. For example, when a pentavalent dopant atom, e.g. phosphorus, arsenic, or antimony, substitutes for a tetravalent atom in a semiconductor, e.g. silicon, the dopant introduce an additional negative charge into the semiconductor as a consequence of the dopant atom's greater valency.

As used herein, the term “p-type” refers to a semiconductor that is doped so that there is an excess of positive charge carriers, i.e. holes. For example, when a trivalent dopant atom, e.g. aluminum or boron, is substituted for a tetravalent atom in a semiconductor, e.g. silicon, the dopant atom introduces an additional positive charge into the semiconductor as a consequence of the dopant atom's smaller valency.

Also, in accordance with a typical pn junction cell design of a PV cell, charge separation of electron-hole pairs is typically confined to a depletion region, which can be limited to a thickness of about 1 μm or less. Electron-hole pairs that are produced further than a diffusion or drift length from the depletion region typically do not charge separate and, thus, typically do not contribute to the conversion into electrical energy. The depletion region is typically positioned within the PV cell at a particular depth below a surface of the PV cell. The variation of the absorption coefficient of silicon across an incident solar spectrum can impose a compromise with respect to the depth and other characteristics of the depletion region that reduces the efficiency of the PV cell. For example, while a particular depth of the depletion region can be desirable for solar radiation at one wavelength, the same depth can be undesirable for solar radiation at a shorter wavelength. In particular, since the shorter wavelength solar radiation can penetrate below the surface to a lesser degree, electron-hole pairs that are produced can be too far from the depletion region to contribute to an electric current. Multi-junction solar cells or tandem cells are solar cells containing several p-n junctions. Each junction can be tuned to a different wavelength of light, reducing one of the largest inherent sources of losses, and thereby increasing efficiency. Traditional single-junction cells have a maximum theoretical efficiency of 34%, a theoretical “infinite-junction” cell would improve this to 87% under highly concentrated sunlight.

N-P junction refers to a connection between a p-type semiconductor and an n-type semiconductor which produces a diode. Depletion region refers to the transition region between an n-type region and a p-type region of an N/P junction where a high electric field exists.

As used herein, the terms “lightly-doped” or “minimally doped” refer to a semiconductor that is only minimally doped so that the electronic structure is more similar to an insulator than it is to a conductor. A doping of less than 10¹⁶ cm⁻³ (e.g., less than 10¹⁵ cm⁻³, 10¹⁴ cm⁻³, 10¹³ cm⁻³) can be considered lightly doped or minimally doped material. In a specific embodiment, the doping is less than 10¹⁴ cm⁻³.

As used herein, the terms “heavily-doped” refer to a semiconductor that is doped to such an extent that the electronic structure is more similar to a conductor than to an insulator. For example, the doping values of 2.5×10¹⁹ and 6.6×10¹⁹ cm⁻³ are associated with heavily doped materials.

As used herein, the term “ultraviolet range” refers to a range of wavelengths from about 5 nm to about 400 nm. As used herein, the term “visible range” refers to a range of wavelengths from about 400 nm to about 700 nm. As used herein, the term “infrared range” refers to a range of wavelengths from about 700 nm to about 2 mm. The infrared range includes the “near infrared range,” which refers to a range of wavelengths from about 700 nm to about 5 μm, the “middle infrared range,” which refers to a range of wavelengths from about 5 μm to about 30 μm, and the “far infrared range,” which refers to a range of wavelengths from about 30 μm to about 2 mm.

Within this description, the term “semiconductive material”, “semiconductor” or “semiconducting substrate” and the like is generally used to refer to elements, structures, or devices, etc. comprising materials that have semiconductive properties, unless otherwise indicated. Such materials include, but are not limited to: materials including elements from Group IV of the periodic table; materials including elements from Group III and Group V of the periodic table, such as, for example, GaAs, GaP, GaAsₓP₁₋ₓ, AlₓGa₁₋ₓ, AlₓGa₁₋ₓAs_{y}P_{1-y}, InₓGa₁₋ₓAs, InₓGa₁₋ₓP, InₓGa₁₋ₓAs_{y}P_{1-y}, AlₓIn₁₋ₓAs_{y}P_{1-y}, AlₓGa₁₋ₓAs_{y}N_{z}P_{1-y-z}, InₓGa₁₋ₓAs_{y}N_{z}P_{1-y-z}, Zn₃P₂, Zn₃S₂, and ZnPₓS₁₋ₓ(0≦x≦1, 0≦y≦1, 0≦z≦1, 0≦y+z≦1); materials including elements from Group II and Group VI of the periodic table; materials including elements from Group I and Group VII of the periodic table; materials including elements from Group IV and Group VI of the periodic table; materials including elements from Group V and Group VI of the periodic table; and materials including elements from Group II and Group V of the periodic table. Other materials with semiconductive properties may include: layered semiconductors; metallic alloys; miscellaneous oxides; some organic materials, and some magnetic materials. The term “semiconducting structure” refers to a structure consisting of, at least in part, a semiconducting material. A semiconducting structure may comprise either doped or undoped material. In some embodiments, the material is minimally doped. As used herein and throughout the disclosure a semiconductive material (sometimes referred to as photoactive material) can be selected from the group consisting of Si, TiO₂, CaTiO₃, SrTiO₃, Sr₃Ti₂O₇, Sr₄Ti₃O₁₀, Rb₂La₂Ti₃O₁₀, Cs₂La₂Ti₃O₁₀, CsLa₂Ti₂NbO₁₀, La₂TiO₅, La₂Ti₃O₉, La₂Ti₂O₇, La₂Ti₂O₇:Ba, KaLaZr_{0.3}Ti_{0.7}O₄, La₄CaTi₅O₁₇, KTiNbO₅, Na₂Ti₆O₁₃, BaTi₄O₉, Gd₂Ti₂O₇, Y₂Ti₂O₇, ZrO₂, K₄N₆O₁₇, Rb₄Nb₆O₁₇, Ca₂Nb₂O₇, Sr₂Nb₂O₇, Ba₅Nb₄O₁₅, NaCa₂Nb₃O₁₀, ZnNb₂O₆, Cs₂Nb₄₀n, La₃NbO₇, Ta₂O₅, KsPrTa₅O₁₅, K₃Ta₃Si₂O₁₃, K₃Ta₃B₂O₁₂, LiTaO₃, KTaO₃, AgTaO₃, KTaO₃:Zr, NaTaO₃:La, NaTaO₃:Sr, Na₂Ta₂O₆, CaTa₂O₆, SrTa₂O₆, NiTa₂O₆, Rb₄Ta₆O₁₇, Ca₂Ta₂O₇, Sr₂Ta₂O₇, K₂SrTa₂O₇, RbNdTa₂O₇, H₂La_{2/3}Ta₂O₇, K₂Sr_{1.5}Ta₃O₁₀, LiCa₂Ta₃O₁₀, KBa₂Ta₃O₁₀, Sr₅Ta₄O₁₅, Ba₂Ta₄O₁₅, H_{1.8}Sr_{0.81}Bi_{0.19}Ta₂C₇, Mg—Ta Oxide, LaTaO₄, LaTaO₇, PbWO₄, RbWNbO₆, RbWTaO₆, CeO₂:Sr, BaCeO₃, NaInO₂, CaIn₂O₄, SrIn₂O₄, LaInO₃, YxIn₂₋ₓO₃, NaSbO₃, CaSb₂O₆, Ca₂Sb₂O₇, Sr₂Sb₂O₇, Sr₂SnO₄, ZnGa₂O₄, Zn₂GeO₄, LiInGeO₄, Ga₂O₃^{b}, Ga₂O₃:Zn^{c}, Na₂Ti₃O₇, K₂Ti₂O₅, K₂Ti₄O₉, Cs₂Ti₂O₅, H⁺—Cs₂Ti₂O₅, Cs₂Ti₅O₁₁, Cs₂Ti₆O₁₃, H⁺—CsTiNbO₅, H⁺—CsTi₂NbO₇, SiO₂-pillared K₂Ti₄O₉, SiO₂-pillared K₂Ti_{2.7}Mn_{0.3}O₇, Na₂W₄O₁₃, H⁺—KLaNb₂O₇, H⁺—RbLaNb₂O₇, H⁺—CsLaNb₂O₇, H⁺—KCa₂Nb₃O₁₀, SiO₂-pillared KCa₂Nb₃O₁₀, ex-Ca₂Nb₃O₁₀/K⁺ nanosheet⁴⁾, Restacked ex-Ca₂Nb₃O₁₀/Na⁺, H⁺—RbCa₂Nb₃O₁₀, H⁺—CsCa₂Nb₃O₁₀, H⁺—KSr₂Nb₃O₁₀, H⁺—KCa₂NaNb₄O₁₃, Bi₂W₂O₉, Bi₂Mo₂O₉, Bi₄Ti₃O₁₂, BaBi₄Ti₄O₁₅, Bi₃TiNbO₉, PbMoO₄, (NaBi)_{0.5}MoO₄, (AgBi)_{0.5}MoO₄, (NaBi)_{0.5}WO₄, (AgBi)_{0.5}WO₄, Ga_{1.14}In_{0.86}O₃, β-Ga₂O₃, Ti_{1.5}Zr_{1.5}(PO₄)₄, WO₃, Bi₂WO₆, Bi₂MoO₆, Bi₂Mo₃O₁₂, Zn₃V₂O₈, Na_{0.5}Bi_{1.5}VMoO₈, In₂O₃ (ZnO)₃, SrTiO₃:Cr/Sb, SrTiO₃:Ni/Ta, SrTiO:Cr/Ta, SrTiO:Rh, CaTiO:Rh, La₂Ti₂O₇:Cr, La₂Ti₂O₇:Fe, TiO₂: Cr/Sb, TiO₂:Ni/Nb, TiO₂:Rh/Sb, PbMoO₄:Cr, RbPb₂Nb₃O₁₀, PbBi₂Nb₂O₉, BiVO₄, BiCu₂VO₆, BiZn₂VO₆, SnNb₂O₆, AgNbO₃, Ag₃VO₄, AgLi_{1/3}Ti_{2/3}O₂, AgLi_{1/3}Sn_{2/3}O₂, LaTiO₂N, Ca_{0.25}La_{0.75}TiO_{2.25}N_{0.75}, TaON, Ta₃N₅, CaNbO₂N, CaTaO₂N, SrTaO₂N, BaTaO₂N, LaTaO₂N, Y₂Ta₂O₅N₂, TiNₓO_{y}F_{z}, Sm₂Ti₂O₅S₂ and La—In oxysulfide.

Further the term “vertical” with reference to wires, rods, whiskers, pillars, etc., generally refers to structures that have a length direction that is elevated somewhat from horizontal.

The term “vertical alignment” generally refers to an alignment or orientation of a structure or structures that is elevated from horizontal. The structure or structures do not have to be completely normal to horizontal to be considered to have a vertical alignment.

The terms “vertically aligned array” or “vertically oriented array” generally refer to arrays of structures where the structures have orientations elevated from a horizontal orientation up to orientations completely normal to a horizontal orientation, but the structures within the array may or may not have all the same orientations with respect to horizontal.

The term “wider band-gap” refers to the difference in band-gaps between a first material and a second material. “Band-gap” or “energy band gap” refers to the characteristic energy profile of a semiconductor that determines its electrical performance, current and voltage output, which is the difference in energy between the valence band maximum and the conduction band minimum. For example, in one embodiment, reference to a wire having a first junction with a “wider band-gap material” refers to a material having a wider band-gap than a second junction of a different material.

Within this description, the terms “wires,” “rods,” “whiskers,” and “pillars” and other similar terms may be used synonymously, except as otherwise indicated. Generally, these terms refer to elongate structures which have lengths and widths, where the length is defined by the longest axis of the structure and the width is defined by the axis generally normal to the longest axis of the structure.

The term “p-i-n junction” as used herein means an assembly comprising three semiconducting materials layers in contact with one another, where one layer is p-doped, a second layer is n-doped, and the third layer is an intrinsic semiconductor layer (“i-layer”), where the i-layer is disposed between the p-layer and the n-layer. Each layer can be doped as is understood by one skilled in the art in view of the semiconducting content of each layer. The term “intrinsic” as used herein means a material in which the concentration of charge carriers is characteristic of the material itself rather than the content of impurities (or dopants). A “heterojunction p-i-n junction” as used herein is a p-i-n junction as defined herein wherein the two semiconducting materials comprising the p-layer and n-layer, respectively, have different alloy composition (notwithstanding the doping content of the layers); the i-layer may comprise the same or a different alloy with respect to the p-layer and/or n-layer.

Si wire arrays grown by the vapor-liquid-solid (VLS) process have emerged as a promising technology for the fabrication of high efficiency, scalable photovoltaics and artificial photosynthetic devices. The photovoltages of Si microwire arrays are not yet comparable, however, to the highest values observed from planar crystalline Si photovoltaics. By analogy to planar Si systems, one approach to improve the photovoltage of the Si microwire arrays could be to operate the system under high-level injection conditions. For lightly doped Si under 1 Sun's illumination, the change in the concentration of photogenerated electrons and holes (Δn and Δp, respectively) can greatly exceed the equilibrium carrier concentrations in the dark (n₀ and p₀). For such samples operated under high-level injection conditions, the Shockley-Read-Hall recombination rate is inversely proportional to the sum of both the carrier lifetimes, and the high-level lifetime is thus longer than the lifetime under low-level injection conditions for a doped semiconductor, where the lifetime is essentially the minority-carrier lifetime.

Planar devices operating under these conditions, such as Si point-contact solar cells, have achieved the highest efficiencies for a single-junction Si photovoltaic, with cell efficiencies >27% under concentrated illumination. These devices utilize lightly doped, float-zone Si, and are fabricated with small interdigitated n⁺ and p⁺ back point-contacts, for the selective collection of electrons and holes, respectively. Such devices do not have significant electric fields in the bulk of the semiconductor, and the photogenerated carriers are therefore driven by diffusion, not drift in the bulk. Accordingly, an extremely long (>1 ms) lifetime, and high-quality surface passivation on both the front and back of the cell is necessary to minimize recombination losses at the surfaces of the device. The n⁺ and p⁺ point contacts are necessary to facilitate the collection photogenerated carriers by strong electric fields at the contacts, in addition to amounting to low saturation currents in the device. This highly optimized structure also benefits from having a highly reflective back surface, an antireflection coating on the front surface, and no shadowing due to the lack of a top contact.

The disclosure provides semiconductive nano- and/or micro-wire arrays (e.g., Si microwire arrays) under high-level injection conditions. The undoped or lightly doped Si microwires are substantially or fully depleted in contact with a chosen redox couple (e.g., Redox couples that form a high barrier height contact such as >0.9 eV), given a wires' acceptor concentrations of N_{A}˜1×10⁻¹³-1×10⁻¹⁴ cm and diameters of ˜2.5-3.0 μm. Previous device physics simulations of doped wires predicted that depleted wires (i.e., wires with small internal electric fields because the fully developed space-charge length would exceed the radius of the wire) should have extremely low carrier-collection efficiencies, due to the absence of a significant electric field within the wire and the lack of majority carriers to facilitate axial carrier transport. In these simulations, the barrier height (0.95 V) was small enough such that the wires did not possess an inversion layer at the surface, providing an electric field at the contact, and also the wires had small diameters. In contrast, for Si microwires in contact with Me₂Fc^{+/0}-CH₃OH, the surface of the wire is expected to be strongly inverted, as demonstrated previously for planar n-Si/Me₂Fc^{+/0}-CH₃OH junctions. Thus, undoped Si microwires that are fully depleted should possess an electric field, with a large concentration of holes at the surface, thereby allowing for efficient carrier collection. Device physics models have previously examined in detail the predicted behavior of fully depleted materials that have relatively short minority-carrier lifetimes and small radii (e.g., <0.5 μm) and consequently have effective diffusion lengths on the order of, or smaller than, the length of the wire.

As described in more detail below, the exemplary Si arrays demonstrated photoanodic behavior in contact with Me₂Fc^{+/0}-CH₃OH even though the wires were slightly p-type in doping. This behavior indicates that the J-E behavior of the arrays was not dominated by their doping, but instead was dominated by the formation of ohmic-selective contacts at the back of the wire through the n⁺ substrate as well as through the conformal, high barrier-height contact provided by the Me₂Fc^{+/0}-electrolyte. The combinations of electrochemical experiments and variation of the growth substrate demonstrated that the back contact of the array, in addition to the electrochemical junction, characterized the photoresponse of the wires. These kinetic asymmetries introduced into the wires by the liquid junction and the back contact were useful to achieve a photoresponse in the microwires. This behavior is analogous to previous observations for p-i-n type Si cells in contact with non-aqueous redox systems. As predicted, no photoresponse was observed for arrays with back contacts that were selective for the same carrier type selected by the radial solution contact (e.g. n⁺ back contacted samples where the electron was collected radially by an electrochemical contact with relatively negative potential).

Photoelectrodes formed using n⁺-i-Si microwires in contact with Me₂Fc^{+/0}-CH₃OH consistently exhibited diode quality factors of n˜1.8-2.0, which is characteristic of devices operating under high-level injection conditions. Diode quality factors of ˜2.0, ranging from n=1.6-1.8, have been measured previously for planar p-i-n concentrator devices in contact with Me₂Fc^{+/0}-CH₃OH. In contrast, previous measurements of p-type Si microwire arrays and of diffused radial junction n⁺p-Si microwire arrays have reported diode quality factors closer to 1.0. Arrays of p-Si microwires in contact with the one-electron redox species methyl viologen, MV^{2+/+}, have displayed n=1.5-1.6 whereas Pt/n⁺p-Si wire arrays in contact with aq. 0.5 M H₂SO₄ display n=1.10±0.04. Single-wire radial p-n junction wires exhibit n values between 1.0-1.2, indicating high-quality, low-recombination p-n junctions operating under low-level injection conditions.

The p⁺-i-Si microwires in contact with CoCp₂^{+/0}-CH₃CN typically produced lower V_{oc} values than their n⁺-i-Si/Me₂Fc^{+/0} counterparts. This slight difference in the photoresponse is consistent with differences in the effective surface recombination velocities for Si in contact with these redox couples. Even for planar n-type and p-type Si photoelectrodes, the n-Si/Me₂Fc^{+/0}-CH₃OH contact typically produces higher V_{oc} values than p-Si/CoCp₂^{+/0}-CH₃CN contacts. Recently, p-Si with a resistivity of ˜0.24 Ω-cm in contact with CoCp2^{+/0}-CH₃CN has produced V_{oc} values of ˜540 mV, while n-Si with the same resistivity measured in contact with Me₂Fc^{+/0}-CH₃OH has produced V_{oc} values of ˜635 mV. In addition, redox couples with more negative electrochemical potentials, such as dimethylcobaltocene^{+/0} in acetonitrile, have elicited higher Voc values from p-Si, demonstrating that the cobaltocene redox system is not completely optimized to produce the maximum photoresponse in Si.

Accordingly, embodiments of the disclosure comprise nano- and/or micro-wires comprising an elongated intrinsic semiconductive core material or a semiconductive material that is light or minimally doped. In one embodiment, a micro- or nano-wire of the disclosure comprises no doping or a doping of less than 10¹⁶, 10¹⁵, 10¹⁴ or 10¹³ cm⁻³. In a specific embodiment, the doping is 10¹⁴ cm⁻³ or less. In another embodiment, the non-doped or minimally-doped nano- or micro-wire further comprises a radial or axial contact. In one embodiment, the radial or axial contact is an electrolyte solution. In another embodiment, the radial or axial contact is a semi-solid or solid. In yet another embodiment, the radial or axial contact is clear or only lightly opaque sufficient to allow light to pass through and contact the nano- or micro-wires.

In another embodiment, the non-doped or minimally doped wires comprise 1 or more p-i-n junctions. A multijunction (sometimes referred to as a tandem junction) device consisting of at least one Si microwire array, wherein each or the microwires are non- or minimally-doped and another photopotential generating junction connected intimately and electrically in series to improve efficiency and the maximum photopotential. This is important for photoelectrosynthetic systems, where the energy in sunlight is directly converted into chemical fuel. For example, in some instances potentials larger than the V_{oc} of a single Si microwire array are required, e.g. H₂/Br³⁻ from HBr; H₂/Cl₂ from HCl; H₂/O₂ from H₂O.

In one embodiment, the disclosure provides a anxially-integrated tandem wire array, wherein a plurality of wires in the array comprise a crystalline Si (c-Si) bottom junction wherein the Si is undoped or minimally doped and has integrated carrier-selective contacts. This may be considered as having a first wire comprising a first semiconductive material (“bottom junction”) and a second wire axially integrated with the first wire comprising a second semiconductive material (“top junction”). In some embodiments, the bottom and top junctions are separated by an ohmic contact. The bottom junction can comprise a minimally doped crystalline Si material that comprises a radial p-i-n, or axial p-i-n, wherein the Si material is only minimally doped. The top junction can be a radial p-n junction, a radial p-i-n junction, an axial p-n junction, or an axial p-i-n junction. The top junction may comprise a more heavily doped material. The semiconductive materials of the top and bottom junctions can be the same or different.

The nano- or micro-wire array comprising undoped or minimally doped elongated semiconductive structures with a carrier-selective back contact can be embedded in a glass, polymer wax or other material to embed or form a membrane (e.g., Nation°). Once embedded the wire array can be mechanically peeled from the growth substrate to make a free-standing device. Furthermore, the as-grown wire arrays can be subsequently in-filled with a polymer or other material and catalyst particles can be deposited on the front and back side of the device. A conductive backing or reflective material such as ITO can be deposited on the surface exposed upon removal from the growth substrate. In yet another embodiment, a catalyst such as a hydrogen or oxygen evolution catalyst can be coated on the device to facilitate, for example, H₂ production from H₂₀. The catalyst can be any number of catalysts useful as hydrogen or oxygen evolution. For example, suitable hydrogen evolution catalyst can be selected from the group consisting of Pt, Co, Cu, Fe, MoSₓ where x is nominally 2, but may be sub or super-stoichiometric, Ni, CoMo, CoW, FeMo, NiCo, NiFe, NiFeC, NiFeS, NiMnS, NiMo, NiMoP, NiSn, NiW, NiZn, NiZnP, CoNiFe, NiCoPMo, NiMoCo, NiMoCu, NiMoFe, NiMoW, NiSiMo, NiSiW and NiWPCu. Suitable oxygen evolution catalysts that can be used in the methods and composition of the disclosure can be selected from the group consisting of IrOₓ where x is nominally 2, but may be sub or super-stoichiometric, Pt, Co, Co/(PO₄)³⁻, Co/(BO₃)³⁻, CoP, Cu, Fe, Mn, Ni, Ni/(BO₃)³⁻, NiP, Pb, CoFe, CoPSc₂O₃, FeMn, NiCo, NiCr, NiCu, NiFe, NiLa, NiLa, NiPSc₂O₃, NiSn, NiZn and NiMoFe.

Such wire arrays or structures comprise, in one embodiment, crystalline Si wires of a length long enough to absorb sunlight fully, each wire with a radius matched to its diffusion length, and the wires being regularly spaced, and oriented predominantly vertically, typically over large areas. The wires are undoped or minimally doped. The wires can be “p” or “n”.

The disclosure also provides a method of making the wire arrays of the disclosure. Embodiments of the disclosure can comprise growing the wire arrays or structures through VLS processes. In such an embodiment, a templating layer is first patterned with openings (e.g., an array of holes) in which the wires or structures are to be grown. The templating layer comprises a diffusion barrier for a deposited catalyst. The diffusion barrier may comprise a patterned oxide layer, a patterned insulating layer, such as a layer comprising silicon nitride, a patterned metal layer, or combinations of these materials or other materials or processes that facilitate the deposition of the catalyst for semiconductor structure growth. The catalyst is then deposited in the openings. Wires or structures are then grown on the substrate by heating the substrate and applying a growth gas.

In one embodiment, a Si <111> wafer is used as the material from which the wire arrays are grown. Other materials may also be used to support wire growth, such as a thin Si layer disposed on glass, or other such Si substrates. All or portions of the wafer may be doped. For example, some embodiments may use a degenerately doped n-type Si wafer. In the process of a surface oxide layer is thermally gown on the wafer. In one embodiment, the surface oxide layer is grown to a thickness of 285 nm. In another embodiment, the surface oxide layer is grown to a thickness of 300 nm. Other embodiments may comprise oxide layers at other thicknesses. Still other embodiments have the oxide layer deposited via chemical vapor deposition (CVD) or other methods known in the art.

A photoresist layer is applied to support the development of a patterned template as discussed below. However, other materials and techniques for creating a patterned template may be used, such as a latex layer, or stamping or soft lithography. The photoresist layer may comprise S1813 photoresist from MicroChem Corp. (Newton, Mass., USA) or other photoresist material. The photoresist layer is then exposed to a desired array pattern and developed with a developer to form a desired pattern of holes in the resist layer. The developer may comprise MF-319 or other developers known in the art. The patterned resist layer is then used to etch the oxide layer on the Si wafer. Etching of the oxide layer may be achieved by using hydrofluoric acid compositions such as buffered HF (9% HF, 32% NH₄F) from Transene Company, Inc. (Danvers, Mass., USA). Other etching techniques known in the art may also be used to etch the oxide layer. The result of the etching will be a pattern of holes in the oxide layer. A pattern of holes may be, for example, a square array of 3 μm diameter holes that are 7 μm center to center.

A growth catalyst is then thermally evaporated onto the resist layer and into the holes in the oxide layer. Other methods of depositing the catalyst may be used, such as electrodeposition. Typical catalysts comprise gold, copper, or nickel, but other metals known in the art as Si V-L-S catalysts may be used, such as platinum or aluminum. For example, 500 nm of gold may be thermally evaporated onto the resist layer and into the holes. Lift-off of the photoresist layer is then performed, leaving catalyst islands separated by the oxide in the oxide layer.

The wafer with the patterned oxide layer and the deposited catalyst may then be annealed. Typically, the annealing is performed in a tube furnace at a temperature between 900 to 1000° C. or at a temperature of about 1050°C. for 20 minutes with the application of 1 atm of H₂ at a flow rate of 1000 seem (where SCCM denotes cubic centimeters per minute at STP). Growth of wires on the wafer is then performed. Typically, the wires are grown in a mixture of H₂ (1000 seem) and SiCl4 (20 sccm) at about 1 atm. In one embodiment, the wires are grown for between 20 to 30 minutes at temperatures between 850° C. to 1100° C.. Other embodiments may use different growth times, pressures, and or flow rates. However, optimal growth temperatures are between 1000° C. and 1050° C.. Growth for these times and at these temperatures may produce wires from 10 μm to 30 μm in length or longer.

Following the growth of the wires, the oxide layer is removed. The oxide layer may be removed by etching the wafer for 10 seconds in 10% HF (aq) or other methods known in the art may be used to remove the oxide layer. Growth catalyst particles may remain at the top of each grown wire, which may impact the functionality of the resulting wire array. Therefore, it may be advantageous to remove the catalyst particles. For example, if the catalyst comprises Au, the gold particles may be removed by soaking the wafer 10 for 10 min in a TFA solution from Transene Company, Inc., which contains I⁻/I₃⁻. Other methods known in the art may also be used to remove catalyst particles.

According to an embodiment of the disclosure, photolithography is a suitable method for enabling uniform arrays of wires of diameters of ˜1 ˜m to be grown over large areas. In cost sensitive applications such as photovoltaics, it may be desirable to employ lower-cost lithographic methods, and embodiments of the disclosure are readily extendable to alternative patterning techniques such as nanoimprint lithography.

Cost also motivates the use of non-Au catalysts for embodiments according to the disclosure. As indicated above, Cu, Ni, Pt, or Al may be used as a catalyst for Si wire growth. Cu is, unlike Au, an inexpensive, earth-abundant material, and, therefore, of particular interest for such embodiments. Although Cu is more soluble in Si than Au and is also a deep trap, Si solar cells are more tolerant of Cu contamination than of Au, and thus diffusion lengths of at least microns even in the case of Cu catalyzed growth can be expected.

The method described above has been shown to produce nearly defect-free arrays that exhibited an extremely narrow diameter and length distribution, and highly controlled wire position.

As discussed above, other growth catalysts may be used to facilitate the growth of the Si wires in the wire array. Nominally identical wire arrays may be obtained when Cu, Ni, Pt, or Al (or other Si growth catalyst metals) are used as the VLS growth catalyst instead of Au.

Use of the oxide layer is useful in some embodiments of the disclosure. For example, Si wire arrays did not yield high pattern fidelity when the catalyst was not confined using the patterned oxide layer as described above.

Upon generation of the micro- and/or nano-wire semiconductor array, a photocatalyst can optionally be deposited onto the wires. In one embodiment, an electrocatalyst bath is prepared comprising a metal salt, where the metal component becomes the bulk of the active catalyst and the salt ion acts as a chelating and solubilizing agent. Stabilizers can be added to the bath and the pH adjusted. For example, in one embodiment, electrocatalyst plating baths comprise a Nickel(II) sulfamate salt, where the Ni component becomes the bulk of the active catalyst and the sulfamate ion acts as a chelating and solubilizing agent. To the solution of Ni(II) is added a small quantity of boric acid as a stabilizer, and the pH is adjusted using sulfamic acid or sodium hydroxide. Optionally, a small amount of molybdenum in the form of sodium molybdate (Na₂MoO₄) is added. Addition of the latter results in improved catalytic activity for the resultant coating toward the hydrogen evolution reaction (HER), due to the formation of a high surface-area alloy of Ni and Mo on the electrode.

The micro- and/or nano-wire semiconductive array (or portion thereof) is immersed in the bath comprising the catalyst to be coated on the substrate. The substrate is then electroplated with the metal catalyst. The electrolytic plating technique comprises placing the photoelectrode on which the catalyst is to be plated into the bath described above, along with a suitable auxiliary electrode (e.g., Ni foil), where upon either a constant voltage (potentiostatic) or constant current (galvanostatic) is applied, using a potentiostat or another available current/voltage source. The magnitude of current that passes between the electrode of interest and the auxiliary electrode should preferably be between about 1 and 100 mA (e.g., 5, 10, 20, 25, 30, 35, 40, 45, 50, 55, 60, 65, 70, 75, 80, 85, 90 or 95 mA) of cathodic current for every cm² of macroscopic surface area for the electrode of interest. Also important is that the photoelectrode must be illuminated with a sufficient photon flux to permit all of the current that flows between its surface and the electrolytic plating solution to be resultant from excited charge carriers generated by the illumination.

Embodiments of the disclosure provide structures that are particularly useful for devices such as solar cells, electronic devices, photonic materials that utilize optical properties of periodic structures of light-absorbing or light-directing materials arranged with structural order in another optically different material, sensors, and similar chemical, optical, and electronic devices and structures.

Embodiments of the disclosure comprise wire arrays or other semiconducting structures with control of the size, position, and uniformity of the fabricated wire arrays or structures over a relatively wide area wherein the arrays comprise wires having tandem or multijunction modes. Such wire arrays or structures can comprise crystalline Si wires of a length long enough to absorb sunlight fully, each wire with a radius matched to its diffusion length, and the wires being regularly spaced, and oriented predominantly vertically, typically over large areas. As mentioned above, the dimensions of the underlying wire arrays are typically from about 1-10 μm in diameter and 10-100 μm or greater in length. Embodiments of the disclosure may comprise growing the wire arrays or structures through VLS processes.

Thus, in one embodiment the disclosure provides an array of rods/wires comprising Si having dimensions of about 1-10 micrometers in diameter and about 1 micrometer to about 1 mm in length, wherein the wires are undoped (intrinsic) or minimally doped.

A particular application for undoped or minimally doped wire arrays fabricated according to embodiments of the disclosure is for the use of such wire arrays in photo cells or fuel generating systems. Device analysis has shown that photovoltaic efficiency is maximized in wire arrays when the mean radius of the wires is comparable to the minority carrier diffusion length. This is because of a trade-off between increased current collection and the loss of open-circuit voltage due to the increased junction and surface area.

Hence, embodiments of the disclosure provide wire arrays with aspect ratios particularly suitable for use in solar cell apparatus. Further, embodiments of the disclosure provide for the ability to have relatively dense arrays of wires, further improving the ability of devices using such arrays to convert light to electrical energy.

The disclosure also provides an artificial photosynthetic system that utilizes sunlight and water, or other solutions that can be used to generate H₂, gas as inputs and produces hydrogen and, for example, oxygen as the outputs. The system comprises three distinct primary components: a photoanode, a photocathode, and a product-separating but ion-conducting membrane. These components may be fabricated and optimized separately before assembly into a complete water-splitting system.

The photoanode and photocathode may comprise arrays of semiconductive microwire structures of the disclosure comprising a metal catalyst. The catalysts disposed on the semiconductive structures are used to drive the oxidation or reduction reactions at low overpotentials. Typically the catalyst coated on the semiconducting structures/substrates do not block or inhibit light energy from contacting the semiconducting wire array or substrate. Accordingly, the catalyst should cover from about 1-99% of the surface area unless sufficiently transparent to allow light penetration to the underlying semiconducting substrate. The high aspect-ratio semiconductor rod/wire electrodes allow for the use of low cost, earth abundant materials without sacrificing energy conversion efficiency due to the orthogonalization of light absorption and charge-carrier collection. Additionally, the high surface-area design of the wire-based semiconductor array electrode inherently lowers the flux of charge carriers over the rod array surface relative to the projected geometric surface of the photoelectrode, thus lowering the photocurrent density at the solid/liquid junction and thereby relaxing the demands on the activity (and cost) of the electrocatalysts. A flexible composite polymer film may be used to allow for electron and ion conduction between the photoanode and photocathode while simultaneously preventing mixing of the gaseous products. That is, the rod/wire arrays may be embedded in flexible, polymeric membrane materials, allowing the possibility of roll-to-roll system assembly. Separate polymeric materials may be used to make electrical contact between the anode and cathode, and also to provide structural support. Interspersed patches of an ion conducting polymer may be used to maintain charge balance between the two half-cells.

In another embodiment, the photoanode and photocathode components may be electrically, and ionically, interconnected through, but physically separated by, a flexible composite polymer film. Further, multi-component membranes, composed of polymeric materials, that exhibit desired mechanical pliability, electronic conductivity, and ion permeability properties for a feasible water electrolysis system may be used. Specifically, polypyrrole may be used to make electrical contact between the anode and cathode, while poly(dimethylsiloxane) (PDMS) may be used to provide structural support for the semiconductor rod/wire arrays. For proton conduction in a cell operated under acidic conditions, Nation® may be employed, whereas vinylbenzyl chloride modified films of poly(ethylene-co-tetrafluoroethylene) (ETFE) may be used for hydroxide conduction in a cell operated under alkaline conditions.

The following examples are meant to illustrate, not limit, the disclosed invention.

### EXAMPLES

Reagents. Methanol (BakerDRY, Mallinckrodt Baker) and lithium perchlorate (battery grade, Sigma-Aldrich) were used as received. 1-1′-dimethylferrocene (Me₂Fc, 95%, Sigma-Aldrich) was purified by sublimation at room temperature, and dimethylferrocenium tetrafluoroborate (Me₂FcBF₄) was synthesized. Acetonitrile (99.8% anhydrous, Sigma-Aldrich) was purified first by sparging with N₂ (g) for 15 min, and then passing the solvent, under pressure from N₂ (g), through a column of activated A2 alumina (Zapp's). Bis(cyclopentadienyl)cobalt(II) (CoCp₂, 98%, Strem) was purified by vacuum sublimation at 65° C.. Cobaltocenium hexafluorophosphate (Cp₂CoPF₆, 98%, Sigma-Aldrich) was recrystallized from an ethanol/acetonitrile mixture (ACS grade, EMD) and dried under vacuum. YLS-catalyzed Si microwire arrays were grown on both n⁺- and p⁺-doped (111)-oriented Si substrates, employing degenerately doped n⁺-Si substrates with a resistivity, ρ˜0.001-0.004 Ω-cra and 450 nm of thermal oxide (University Wafer) or p⁺-Si substrates with ρ˜0.001-0.005 Ω-cm and 500 nm of thermal oxide (International Wafer Service).

VLS-Catalyzed Microwire Growth. Arrays of square-packed Si microwires were grown on planar n⁺- and p⁺-Si(111) substrates using a vapor-liquid-solid (VLS) growth method with a Cu catalyst (99.9999%, ESPI) and without dopants. For photoelectrochemical measurements under 1 Sun of light intensity, the resulting undoped wires grown on an n⁺-Si substrate (n⁺-Si microwires), were 2.7-2.9 μm in diameter and 67-80 μm in height (FIG. 1). The p⁻-Si microwires were 1.65-1.75 μm in diameter and 90-97 μm in height. The n⁻-Si wires that were used for the spectral response and optical measurements were 2.1-2.3 μm in diameter and 65-75 μm in height. After wire growth, the Cu VLS catalyst was removed by a 5 s buffered HF(aq) (BHF, Transene Inc.) etch, followed immediately by an etch in 6:1:1 (by volume) of H₂O:HCl:H₂O₂ at 70° C. (RCA 2) for 15 min. This BHF/RCA2 procedure was the repeated to ensure that all of the metal catalyst had been removed. Four-point resistance measurements on single wires were performed as described previously, for wires grown on both n⁺- and p⁺-Si substrates.

The undoped Si microwires had a resistivity of 800±500 Ω-cm as grown on n⁺ substrates and a resistivity of 200±100 Ω-cm on p⁺-Si (111) substrates. For wires grown on either n⁺ and p⁺-Si substrates, gate-dependent conductance measurements indicated that the microwires were slightly p-type, and showed an increase in conductivity with a negative applied gate-bias. The as-grown microwires thus possessed low electronically active acceptor concentrations, Nₐ, of ˜1×10¹³ to 1×10¹⁴ cm⁻³.

Electrode Fabrication. To fabricate multiple electrodes for photoelectrochemical measurements, arrays of Si microwires were cleaved into ˜4×4 mm samples. A SiC scribe was used to scratch Ga:In eutectic into the backs of the samples, thereby producing an ohmic contact to the Si substrate. Ag print (GC Electronics) was then used to affix the samples to a coiled wire that had been passed through a glass tube, with the resulting electrode positioned in a face-down configuration. A low-creep epoxy (Loctite 9460 F) was used to define the electrode active area, and a higher stability epoxy (Hysol 1C) was used to encapsulate the back contact and wire coil. The electrodes were placed for 4 h in an oven heated to 70° C., to further cure the epoxy, thereby obtaining enhanced chemical stability in both the CH₃OH and CH₃CN solutions. The electrode areas were ˜0.03 cm₂, as measured using a high-resolution scanner and analyzed by Adobe Photoshop software.

Photoelectrochemical Measurements. All non-aqueous photoelectrochemical current density vs. potential (J-E) measurements were performed with bottom illumination in air-tight, flat-bottomed glass cells. The Me₂Fc^{+/0}-CH₃OH electrolyte solution consisted of 200 mM of Me₂Fc, 0.4 mM of Me₂FcBF₄, and 1.0 M LiClO₄ in 30 mL of methanol. The cell was assembled and sealed under an inert atmosphere (<10 ppm O₂), and subsequently was placed under a positive Ar pressure on a gas manifold. A high-surface area Pt mesh was used as the counter electrode, and the reference electrode was a Pt wire in a Luggin capillary that had been filled with the same solution as that in the main cell compartment. The difference between the Nernstian potential of the solution and the potential of the reference electrode was recorded using a 4-digit voltmeter (Keithley), with the value differing from the reference electrode potential by <10 mV. J-E measurements were obtained at a scan rate of 5 mV s⁻¹.

The CoCp₂^{+/0}-CH₃CN electrolyte solution consisted of 50 mM of CoCp₂PF₆, 5.0 mM of CoCp₂, and 1.0 M LiClO₄ in 20 mL of acetonitrile. The cell was assembled and used under an inert, dry atmosphere (<0.50 ppm O₂; 0.5 ppm H₂O). The counter electrode was a high-surface area Pt mesh as the counter electrode and the reference electrode was a Pt wire in solution in close proximity to the working electrode. A Luggin capillary was not used as a reference electrode in this cell, due to the instability and relatively low concentrations of CoCp₂ in the electrolyte. The J-E measurements were obtained at a scan rate of 30 mV s⁻¹, to limit the solution optical absorption produced by generation of CoCp₂ at the working electrode.

A 300 W ELH-type tungsten halogen bulb with a dichroic rear reflector and diffuser was used as the illumination source for electrochemical measurements under simulated 1 Sun illumination in contact with Me₂Fc^{+/0}-CH₃OH or CoCp₂^{+/0}-CH₃CN. The incident light intensity was calibrated using a Si photodiode that was placed in the solution at the position of the working electrode. The light intensity was adjusted until the short-circuit photocurrent of the Si diode was the same as the short-circuit photocurrent produced on the photodiode by 100 mW cm⁻² of AM 1.5 G illumination. The Si electrodes were etched for 5 s in 5% HF(aq), rinsed with >18 MΩ-cm resistivity H₂O, and dried thoroughly under a stream of N₂ (g) prior to photoelectrochemical measurements. The electrochemical cells were vigorously stirred during J-E measurements. Data were collected and averaged for seven wire array samples, for both wire array photoelectrodes tested in Me₂Fc^{+/0} and CoCp₂^{+/0} electrochemical cells.

To reduce concentration overpotential losses within the Me₂Fc^{+/0}-CH₃OH cell and to demonstrate the validity of the corrections for these losses, J-E measurements were also performed for electrolytes that had 40 mM Me₂FcBF4 added to the cell (see Supporting Information for calculations). The cells were illuminated using a 1 W 808 nm diode laser (Thorlabs), and J-E data were collected by matching the Jsc value to the value of Jsc that was obtained under 1 Sun ELH-type W-halogen illumination for each electrode. This process required ˜55 mW cm⁻² of 808 nm illumination, as measured by a calibrated Si photodiode (FDS-100, Thorlabs) placed in the electrochemical cell at the position of the working electrode.

To determine the diode quality factor of the Si microwire photoelectrodes in contact with Me₂Fc^{+/0}-CH₃OH, the J-E behavior was measured at a series of light intensities under 808 nm illumination. At each light intensity, the V_{oc} was initially measured using a Keithley 4-digit voltmeter, and the J_{sc} was measured from the J-E behavior of the electrode. The V_{oc} is expected to the have the general form:

$$\text{?} = \frac{\text{?}}{\text{?}} ln ( \frac{\text{?}}{\text{?}} ) \\ \text{?} \text{indicates text missing or illegible when filed} \qquad ( 1 )$$

where n is the diode quality factor, k is Boltzmann's constant, T is the absolute temperature, q is the unsigned charge on an electron, Jₚₕ is the photocurrent density, and J₀ is the dark saturation current density. Therefore, a plot of V_{oc} versus ln(Jₚₕ) should be linear with a slope of nkT/q, allowing for straight forward determination of the value of n. To calculate the diode quality factor, the behavior of the n⁺i-Si microwire array photoelectrodes was measured under 808 nm illumination ranging in light intensity from ˜13 mW cm⁻² to 165 mW cm⁻², corresponding to ˜0.24-3.0 Suns of illumination.

Angle-resolved Spectral Response and Optical Measurements. Angle-resolved spectral response and optical measurements of Si microwire arrays were obtained using a chopped (f=30 Hz) Fianium super continuum laser coupled to a monochromator, in conjunction with two rotational stages that permitted rotation of the sample around both the θₓ and θ_{y} axes. The angle-resolved spectral response measurements were obtained using side-facing electrodes of high-fidelity Si microwire arrays, with overall electrode dimensions of ˜7×7 mm. The electrodes were fabricated so that the Si microwire arrays would ultimately be eucentric with respect to the rotational axes, θ_{y} and θₓ, and electrodes were oriented accordingly. The Me₂Fc^{+/0}-CH₃OH electrochemical cell contained a solution of 10 mM of Me₂Fc, 0.4 mM of Me₂FcBF₄, and 1.0 M LiClO₄ in 25 mL of methanol, and was maintained under a positive pressure of Ar during the experiments. The photoelectrode was aligned in the cell by utilizing the reflected optical diffraction pattern, and normal incidence (θ_{x,y}=0°) was determined by minimizing the photocurrent of each electrode. A calibrated Si photodiode (FDS-100, Thorlabs) that was positioned inside the cell was used to calculate the external quantum yield, Γₑₓₜ, of the Si microwire array photoelectrodes.

An integrating sphere was used to perform optical transmission and reflection measurements as a function of the wavelength (λ) and incident angle (θ_{y}) of illumination on peeled-off films of Si microwires embedded in polydimethylsiloxane (PDMS; Sylgard 184, Dow Corning). Optical measurements were made on peeled arrays formed using pieces of the Si microwire array that were adjacent to the pieces used for measurement of the spectral response. Because the heights of the wires can vary across one growth chip, care was taken to measure wires with the same heights for the optical and photoelectrochemical measurements, by using adjacent portions of the same array, with the samples located at equal distances from the growth front on the chip. The optical diffraction patterns of the arrays were used to orient the films relative to the rotational axes (θₓ, θ_{y}). The maximization of transmission in the films was taken to be normal incidence to the wire array.

To determine the effect of the Cu silicide region on the carrier-collection efficiency of undoped Si microwires, this region, located at the tops of the wires, was selectively removed by chemical-mechanical polishing. Arrays of n⁺-i-Si microwires were fully embedded with mounting wax and subsequently polished by hand using powder A1203 and silica suspensions. Half of each array was reserved as a control, to provide a direct comparison for spectral response and optical measurements, respectively, between the same wires in the measurements of polished and unpolished electrodes and films.

Device Physics Simulations. Device physics simulations were carried out using Sentaurus Device from Synopsis Inc. Wires were defined in two dimensions (2D) using cylindrical coordinates. A liquid contact was simulated using a Schottky-type contact that formed a high barrier-height contact with n-Si. Electron and hole recombination velocities were set to 1×10⁷ cm s⁻¹. Scanning photocurrent simulations were conducted by scanning a simulated light beam axially along a wire. The contacts for the wire included the high barrier-height contact, which was applied radially to the wire, and an n⁺ back-surface field that acted as an electron-selective contact. The distance=0 μm was defined to be the tip of the wire (far from the n⁺ back surface field), and the wire was 70 μm in length. The quantum yield for carrier collection at zero applied voltage was determined by integrating the total number of excitations per unit time in the wire and dividing that quantity into the number of electrons collected per unit time derived from the current at the contacts. The dopant density was uniform throughout the wire, except at the base of the wire were the back-surface field was present. The mobility assumed bulk values that decreased with increasing dopant densities according to empirically developed and well-established relationships. A Shockley-Read-Hall lifetime was set for each simulation (τₙ=τₚ) and the value was adjusted based on the empirical relationship with the dopant density given in eq. 2,

$$\text{?} = \frac{\text{?}}{\text{?}} \\ \text{?} \text{indicates text missing or illegible when filed} \qquad ( 2 )$$

where N is the dopant density, N_{ref}=1×10¹⁶ cm⁻³, rn is the initial value set for the carrier lifetime, and r_{SRH} is the final value used in computing recombination rates.

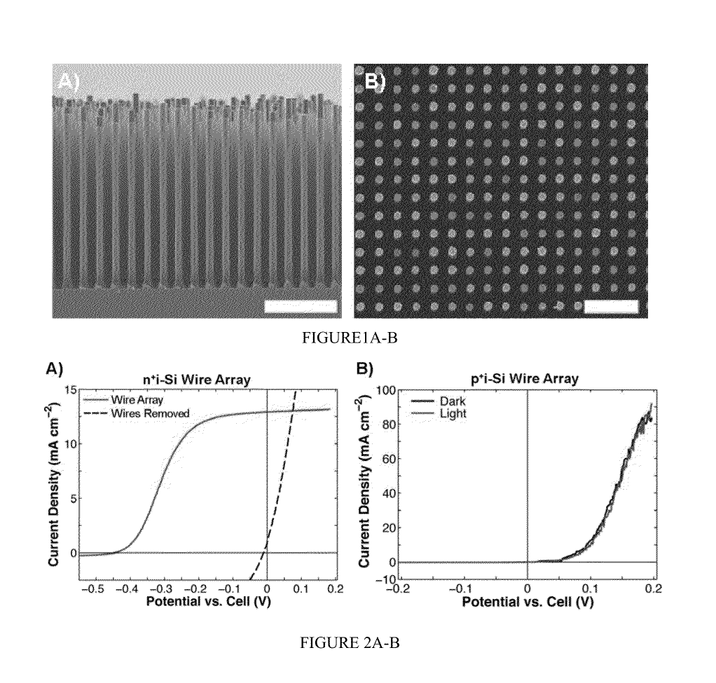

Photoelectrochemical Behavior of Intrinsically Doped Si Microwires in Contact with Me₂Fc-CH₃OH and CoCp₂^{+/0}-CH₃CN Electrolytes. FIG. 2 shows the J-E behavior of the n⁺i- and p⁺i-Si microwire array photoelectrodes in contact with Me₂Fc^{+/0}-CH₃OH under 1 Sun of simulated solar illumination. The n⁺i-Si microwire electrodes exhibited V_{oc}=445±13 mV, J_{sc}=12.8±2.1 mA cm⁻², fill factors, ff, of 0.41±0.03, and a photoelectrode energy-conversion efficiency, η, of 2.3±0.3%. In contrast, the p⁺i-Si microwire array photoelectrodes showed no photoresponse in contact with this electrolyte. For all electrodes, the degenerately doped growth substrates did not significantly contribute to the measured photoresponse of the wire arrays, as indicated by measuring the photoresponse of the electrodes with the wires were removed from the substrate through use of non-abrasive mechanical force.

FIG. 3 shows the photoresponse of the same n⁺i- and p⁺i-Si microwire array electrodes measured in contact with the CoCp₂^{+/0}-CH₃CN electrolyte. The p⁺i-Si electrodes behaved as photocathodes in contact with the CoCp₂^{+/0} redox couple, exhibiting V_{oc}=421±14 mV, J_{sc}=−10.9±0.3 mA cm⁻², ff=0.32±0.02, and η=1.5±0.1%. Consistent with measurements of p⁺i-Si in contact with Me₂Fc^{+/0}-CH₃OH, the n⁺i-Si showed no photoresponse in contact with CoCp₂^{+/0}-CH₃CN.

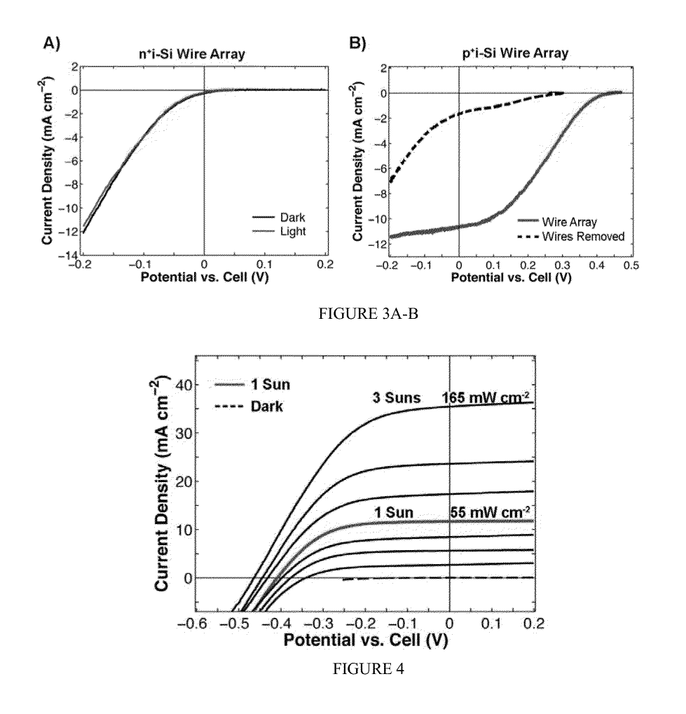

To reduce parasitic losses from concentration overpotential effects within the cell, the J-E response of the n⁺i-Si microwire electrodes was also measured in contact with Me₂Fc^{+/0}-CH₃OH in the presence of a higher concentration of the oxidized form of the redox couple, Me₂Fc⁺. Under these conditions, the n⁺i-Si microwire photoelectrodes exhibited fill factors of ffsos=0.58±0.02 and an efficiency η_{808 nm}=5.9±1.0% under 55 mW cm⁻² of 808 nm illumination, along with diode quality factors of n=1.90±0.07(FIG. 4). After correcting the J-E data for losses due to the concentration overpotential and uncompensated cell resistance, the corrected fill factor and photoelectrode efficiency values were ff_{corr}=0.62±0.04 and η_{corr}=3.5±0.6%, respectively.

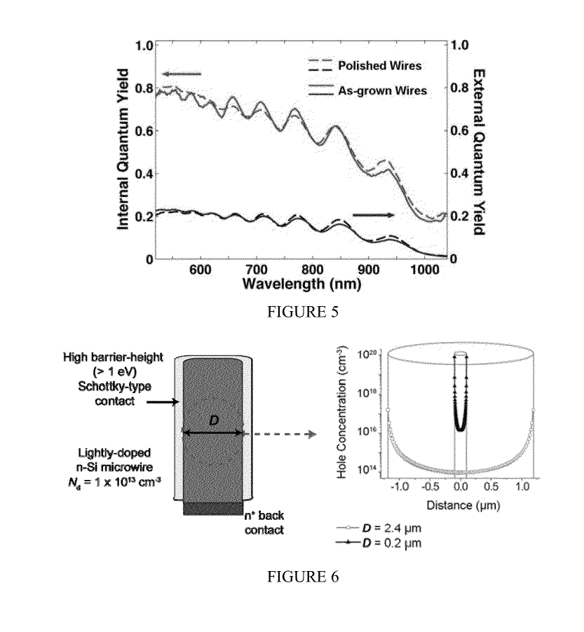

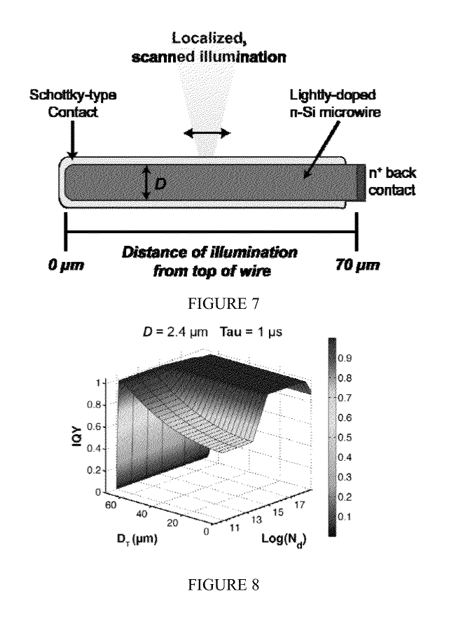

To investigate the carrier-collection efficiency of the undoped Si microwire arrays, measurements of the external and internal quantum yields were performed on n⁺i-Si photoelectrodes in contact with Me₂Fc^{+/0}-CH₃OH. Given the anisotropy of light absorption within an array with respect to the angle of incident illumination, the spectral response and optical measurements were performed at normal incidence. The maximum external quantum yield of the n⁺i-Si photoelectrodes was Γₑₓₜ˜0.23 under visible illumination, while the maximum value of Γᵢₙₜ˜0.79 (FIG. 5) was in good agreement with previous measurements on undoped Si microwire array photoanodes. Both γₑₓₜ and Γᵢₙₜ showed no change between as-grown wires that contained the Cu silicide region near the tip and polished wires for which the silicide had been removed. Thus, for the undoped Si microwire arrays, the presence of the interfacial region at the tops of the wires had no measurable effect on the carrier-collection efficiency within the wires.

Device Physics Model of the Photoelectrochemical Behavior of n⁺i-Si Microwire Arrays in Contact with Me₂Fc^{+/0}-CH₃OH. The carrier concentration within a single n⁺i-Si microwire while in contact with Me₂Fc^{+/0}-CH₃OH in the dark at zero applied bias was calculated using Sentaurus Device. At diameters D of either 0.2 or 2.4 μm, the lightly doped n-Si wires with Nd=1×10¹³ cm⁻³ had high concentrations of holes throughout the volume of the wires (FIG. 6). The smaller diameter D=0.2 μm wire was calculated to be strongly inverted, with a background concentration of holes exceeding 1×10¹⁶ cm⁻³ within the core and approaching 1×10²⁰ cm⁻³at the surface of the wire. The larger diameter D=2.4 μm wire was calculated to be weakly inverted, but still possessed hole carrier concentrations that exceeded the background concentration of the wire when not in contact with Me₂Fc-CH₃OH.

The carrier-collection efficiency within a single wire was calculated for a wire having a typical diameter of D=2.4 μm, while the dopant density was varied from N_{d}=1×10¹¹-3×10¹⁹ cm⁻³(FIG. 8). The Shockley-Read-Hall lifetime was fixed at a value of r_{SRH}=1 μs, which corresponds to an effective diffusion length for electrons of ˜60 μm assuming an electron mobility μₑ˜1400 cm2 V⁻¹ s⁻¹. This lifetime was a realistic value for a first simulation, given that L_{eff} values ranging from 10 μm to >>30 μm have been measured for single-wire Si p-n junctions. The use of this particular lifetime also guaranteed that, for the fixed D employed, radial collection would be unity for moderately doped wires, in agreement with previous work on the behavior of radial p-n junctions. However, for wires with N_{d}<1×10¹⁵ cm⁻³, the carrier-collection efficiency deviated from unity, particularly for carriers generated at the top of the wire. This result can be understood in light of the carrier concentration within the wire, because the wires were fully inverted, with a background concentration of holes greater than the background concentration of electons, under the simulation conditions. Hence, the high concentration of holes throughout the n-type wire produced an increase in the recombination rate for electrons within the wire. The photogenerated electrons must be transported down the length of the wire to be collected at the back contact, but instead can undergo recombination with the large concentration of holes throughout the wire. Thus, under these simulation conditions, the performance of this device architecture was limited by electron transport down the length of the wire. Wires with N_{d}˜1×10¹⁵-1×10¹⁸ cm⁻³ were calculated to exhibit Γᵢₙₜ=1, in agreement with previous simulations for wires with radii R<L_{eff}. For wires with N_{d} exceeding ˜5×10¹⁸ cm⁻³, other recombination mechanisms such as Auger recombination began to dominate, decreasing the overall lifetime and ultimately limiting the radial collection of carriers.

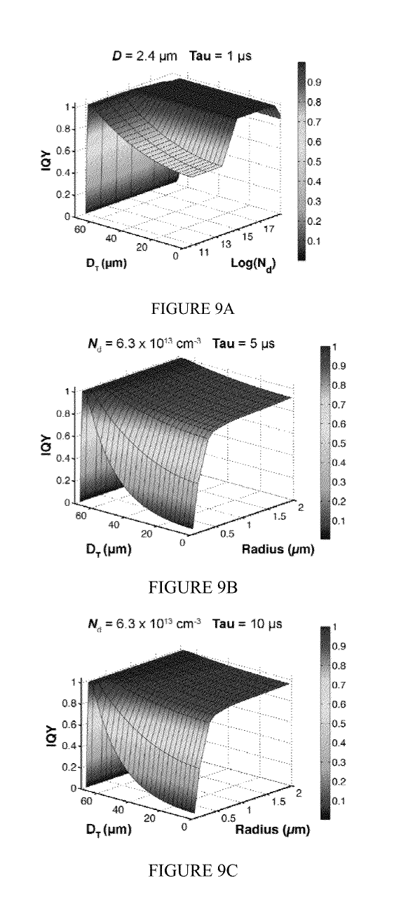

The carrier-collection efficiency within a single, lightly doped wire was also calculated as a function of the radius of the wire and the Shockley-Read-Hall lifetime (FIG. 9). Both varied parameters had a significant effect on the internal quantum yield. For wires with R<0.5 μm, the carrier-collection efficiency precipitously decreased relative to wires having larger radii. This result is consistent with the expected complete depletion of electrons within the wire at these diameters, and with the presence of a hole-rich inversion layer in the near-surface region, ˜100 nm in depth into the wires. At such small radii, the wires are strongly inverted throughout the radial dimension, resulting in high recombination rates for electrons traversing down the length of the wire.

The internal quantum yield also demonstrated a significant dependence on the fixed lifetime within the range of 1-10 μs, with Γᵢₙₜ approaching values >0.9 in wires with τ=10 μs. Assuming an electron mobility μₑ˜1400 cm2 V⁻¹ s⁻¹, this lifetime corresponds to L_{eff}=60-190 μm. Thus, to collect the majority of carriers in a 70 μm long wire, the effective diffusion length must be ˜3 times greater than the length of the wire. Hence even though the device was structured to facilitate the radial collection of carriers, the axial transport of electrons ultimately limits the carrier-collection within the device, necessitating the use of a material with a long diffusion length and large diameter.

Although a number of embodiments and features have been described above, it will be understood by those skilled in the art that modifications and variations of the described embodiments and features may be made without departing from the teachings of the disclosure or the scope of the invention as defined by the appended claims.

What is claimed is:

1. A device comprising:
a back contact layer;
an ordered array of elongated intrinsic or lightly doped semiconductor structures, wherein the elongate structures have length dimensions defined by adjacent ends in electrical contact with at least portions of the back contact layer and distal ends not in contact with the back contact layer and have radial dimensions generally normal to the length dimensions and the radial dimensions are less than the length dimensions and wherein the diameters of the elongated structures are greater than 500 nm; and
an axial or radial contact layer or medium, wherein at least some portions of the axial or radial contact layer or medium are in electrical contact with one or more elongate structures of the plurality of the elongate structures along at least portions of the length dimensions of the one or more elongate semiconductor structures, wherein the elongate structures absorb received light.

2. The device according to claim 1, wherein the radial dimensions are less than or equal to minority carrier diffusion lengths for material comprising the elongate semiconductor structures.

3. The device of claim 1, wherein the elongated structures comprise minority carrier lifetimes of greater than 1 μs.

4. The device of claim 1, wherein the elongated structures comprise diameters greater than 500 nm.

5. The device of claim 1, wherein the elongated structures comprise diameters of about 1.75 μm to 3 μm.

6. The device of claim 1, wherein the elongated structures' acceptor concentrations (Na) are ˜1×10¹³ to 10¹⁴ cm⁻³.

7. The device of claim 1, wherein the elongated structures' donor acceptor concentrations (Nd) are ˜1×10¹³ to 10¹⁴ cm⁻³

8. The device of claim 1, wherein when the back contact is an n⁺-type contact the radial or axial contact is p⁺-type.

9. The device of claim 1, wherein when the back contact is a p⁺-type contact the radial or axial contact is n⁺-type.

10. The device of claim 1, wherein upon illumination, the elongated structure produces 450 or greater mV.

11. The device of claim 1, wherein the device displays high level injection characteristics.

12. The device of claim 1, wherein the base contact layer comprises a substrate and the elongate semiconductor structures comprise structures grown from the substrate.

13. The device of claim 1, wherein the base contact layer comprises a substrate and the elongate semiconductor structures comprise structures deposited on the substrate.

14. The device of claim 1, wherein the axial or radial contact layer comprises a liquid electrolyte.

15. The device of claim 1, further comprising a catalyst in contact with the back contact layer.

16. The device of claim 1, further comprising a catalyst in contact with the elongated structures.

17. The device of claim 15 or 16, wherein the catalyst is a hydrogen evolution catalyst selected from the group consisting of Pt, Co, Cu, Fe, MoSₓ where x is nominally 2, but may be sub or super-stoichiometric, Ni, CoMo, CoW, FeMo, NiCo, NiFe, NiFeC, NiFeS, NiMnS, NiMo, NiMoP, NiSn, NiW, NiZn, NiZnP, CoNiFe, NiCoPMo, NiMoCo, NiMoCu, NiMoFe, NiMoW, NiSiMo, NiSiW and NiWPCu.

18. The device of claim 15 or 16, wherein the catalyst is an oxygen evolution catalyst selected from the group consisting of IrOₓ where x is nominally 2, but may be sub or super-stoichiometric, Pt, Co, Co/(PO₄)⁻³, Co/(BO₃)⁻³, CoP, Cu, Fe, Mn, Ni, Ni/(BO₃)⁻³, NiP, Pb, CoFe, CoPSc₂O₃, FeMn, NiCo, NiCr, NiCu, NiFe, NiLa, NiPSc₂O₃, NiSn, NiZn and NiMoFe.

19. The device of claim 1, wherein the elongated structure comprise a material selected from the group consisting of elements from Group IV of the periodic table; elements from Group III and Group V of the periodic table; elements from Group II and Group VI of the periodic table; elements from Group I and Group VII of the periodic table; elements from Group IV and Group VI of the periodic table; elements from Group V and Group VI of the periodic table; and elements from Group II and Group V of the periodic table.

20. The device of claim 19 , wherein the elongated structure comprises a material selected form the group consisting GaAs, GaP, GaAsₓP₁₋ₓ, AlₓGa₁₋ₓ, As, AlₓGa₁₋ₓAs_{y}P_{1-y}, InₓGa₁₋ₓAs, InₓGa₁₋ₓP, InₓGa₁₋ₓAs_{y}P_{1-y}, AlₓIn₁₋ₓAs_{y}P_{1-y}, AlₓGa₁₋ₓAs_{y}N_{z}P_{1-y-z}, InₓGa₁₋ₓAs_{y}N_{z}P_{1-y-z}, Zn₃P₂, Zn₃S₂, and ZnPₓS₁₋ₓ(0≦x≦1, 0≦y≦1, 0≦z≦1, 0≦y+z≦1).

21. The device of claim 19, wherein the elongated structure comprises a material selected from the group consisting of TiO₂, CaTiO₃, SrTiO₃, Sr₃Ti₂O₇, Sr₄Ti₃O₁₀, Rb₂La₂Ti₃O₁₀, Cs₂La₂Ti₃O₁₀, CsLa₂Ti₂NbO₁₀, La₂TiO₅, La₂Ti₃O₉, La₂Ti₂O₇, La₂Ti₂O₇:Ba, KaLaZr_{0.3}Ti_{0.7}O₄, La₄CaTi₅O₁₇, KTiNbO₅, Na₂Ti₆O₁₃, BaTi₄O₉, Gd₂Ti₂O₇, Y₂Ti₂O₇, ZrO₂, K₄N₆O₁₇, Rb₄Nb₆O₁₇, Ca₂Nb₂O₇, Sr₂Nb₂O₇, Ba₅Nb₄O₁₅, NaCa₂Nb₃O₁₀, ZnNb₂O₆, Cs₂Nb₄₀n, La₃NbO₇, Ta₂O₅, KsPrTa₅O₁₅, K₃Ta₃Si₂O₁₃, K₃Ta₃B₂O₁₂, LiTaO₃, KTaO₃, AgTaO₃, KTaO₃:Zr, NaTaO₃:La, NaTaO₃:Sr, Na₂Ta₂O₆, CaTa₂O₆, SrTa₂O₆, NiTa₂O₆, Rb₄Ta₆O₁₇, Ca₂Ta₂O₇, Sr₂Ta₂O₇, K₂SrTa₂O₇, RbNdTa₂O₇, H₂La_{2/3}Ta₂O₇, K₂Sr_{1.5}Ta₃O₁₀, LiCa₂Ta₃O₁₀, KBa₂Ta₃O₁₀, Sr₅Ta₄O₁₅, Ba₂Ta₄O₁₅, H_{1.8}Sr_{0.81}Bi_{0.19}Ta₂C₇, Mg—Ta Oxide, LaTaO₄, LaTaO₇, PbWO₄, RbWNbO₆, RbWTaO₆, CeO₂:Sr, BaCeO₃, NaInO₂, CaIn₂O₄, SrIn₂O₄, LaInO₃, YxIn₂₋ₓO₃, NaSbO₃, CaSb₂O₆, Ca₂Sb₂O₇, Sr₂Sb₂O₇, Sr₂SnO₄, ZnGa₂O₄, Zn₂GeO₄, LiInGeO₄, Ga₂O₃^{b}, Ga₂O₃:Zn^{c}, Na₂Ti₃O₇, K₂Ti₂O₅, K₂Ti₄O₉, Cs₂Ti₂O₅, H⁺—Cs₂Ti₂O₅, Cs₂Ti₅O₁₁, Cs₂Ti₆O₁₃, H⁺—CsTiNbO₅, H⁺—CsTi₂NbO₇, SiO₂-pillared K₂Ti₄O₉, SiO₂-pillared K₂Ti_{2.7}Mn_{0.3}O₇, Na₂W₄O₁₃, H⁺—KLaNb₂O₇, H⁺—RbLaNb₂O₇, H⁺—CsLaNb₂O₇, H⁺—KCa₂Nb₃O₁₀, SiO₂-pillared KCa₂Nb₃O₁₀, ex-Ca₂Nb₃O₁₀/K⁺ nanosheet⁴⁾, Restacked ex-Ca₂Nb₃O₁₀/Na⁺, H⁺—RbCa₂Nb₃O₁₀, H⁺—CsCa₂Nb₃O₁₀, H⁺—KSr₂Nb₃O₁₀, H⁺—KCa₂NaNb₄O₁₃, Bi₂W₂O₉, Bi₂Mo₂O₉, Bi₄Ti₃O₁₂, BaBi₄Ti₄O₁₅, Bi₃TiNbO₉, PbMoO₄, (NaBi)_{0.5}MoO₄, (AgBi)_{0.5}MoO₄, (NaBi)_{0.5}WO₄, (AgBi)_{0.5}WO₄, Ga_{1.14}In_{0.86}O₃, β-Ga₂O₃, Ti_{1.5}Zr_{1.5}(PO₄)₄, WO₃, Bi₂WO₆, Bi₂MoO₆, Bi₂Mo₃O₁₂, Zn₃V₂O₈, Na_{0.5}Bi_{1.5}VMoO₈, In₂O₃ (ZnO)₃, SrTiO₃:Cr/Sb, SrTiO₃:Ni/Ta, SrTiO:Cr/Ta, SrTiO:Rh, CaTiO:Rh, La₂Ti₂O₇:Cr, La₂Ti₂O₇:Fe, TiO₂: Cr/Sb, TiO₂:Ni/Nb, TiO₂:Rh/Sb, PbMoO₄:Cr, RbPb₂Nb₃O₁₀, PbBi₂Nb₂O₉, BiVO₄, BiCu₂VO₆, BiZn₂VO₆, SnNb₂O₆, AgNbO₃, Ag₃VO₄, AgLi_{1/3}Ti_{2/3}O₂, AgLi_{1/3}Sn_{2/3}O₂, LaTiO₂N, Ca_{0.25}La_{0.75}TiO_{2.25}N_{0.75}, TaON, Ta₃N₅, CaNbO₂N, CaTaO₂N, SrTaO₂N, BaTaO₂N, LaTaO₂N, Y₂Ta₂O₅N₂, TiNₓO_{y}F_{z}, Sm₂Ti₂O₅S₂ and La—In oxysulfide.

22. The device of claim 1, wherein the elongated structure comprise Si.

23. The device of claim 1, wherein the elongated structure comprise at least one of the following materials: crystalline silicon; amorphous silicon; micromorphous silicon; protocrystalline silicon; nanocrystalline silicon; cadmium telluride; copper-indium selenide; copper indium gallium selenide gallium arsenide; gallium arsenide phosphide; cadmium selenide; indium phosphide; a-Si:H alloy, and combinations thereof.

24. A photocell comprising a device of claim 1.

25. A photocell for conversion of water to hydrogen comprising a device of claim 15 or 16.
